(19) United States
(12) Patent Application Publication
(10) Pub. No.: US 2024/0054755 A1
(43) Pub. Date: Feb. 15, 2024

(54) SENSOR DEVICE AND METHOD OF DETERMINING CORRECTION COEFFICIENTS

(71) Applicant: Shanghai Tianma Micro-Electronics Co., Ltd., Shanghai (CN)

(72) Inventors: Genshiro KAWACHI, Kanagawa (JP); Hiroshi HAGA, Kanagawa (JP); Feng LU, Shanghai (CN); QiJun YAO, Shanghai (CN); Haochi YU, Shanghai (CN)

(21) Appl. No.: 18/364,871

(22) Filed: Aug. 3, 2023

(30) Foreign Application Priority Data
Aug. 9, 2022 (JP) 2022-127099

(51) Int. Cl. G06V 10/60; G06V 10/141; G06V 10/75

(52) U.S. Cl. CPC G06V 10/60; G06V 10/141; G06V 10/758

(57) ABSTRACT

A sensor device includes a plurality of pixels and a controller configured to correct measurement signals of the plurality of pixels. Each of the plurality of pixels includes a photodetector and a pixel circuit configured to output a signal from the photodetector. The controller is configured to acquire an unknown measured signal from one of the plurality of pixels, and correct the unknown measured signal of the one pixel with a correction coefficient which is based on ratios between values obtained from measured signals of the one pixel under a plurality of reference lights having different intensities and statistic values obtained from the values obtained from the measured signals of the plurality of pixels under a plurality of reference lights having different intensities.

### CROSS-REFERENCE TO RELATED APPLICATIONS

This non-provisional application claims priority under 35 U.S.C. § 119(a) on Patent Application No. 2022-127099 filed in Japan on Aug. 9, 2022, the entire content of which is hereby incorporated by reference.

### BACKGROUND

This disclosure relates to a technology for reducing the noise in signals from photodetectors.

The noise included in a signal output from a photoimaging element is categorized into random noise that varies with time and fixed-pattern noise (FPN) that does not vary with time. The FPN is further categorized into two kinds of FPN: dark-time FPN and bright-time FPN. The dark-time FPN is observed when the photoimaging element is not receiving light. The bright-time FPN varies in intensity depending on the intensity of incident light. It is known that the dark-time FPN is caused by variations in input and output characteristics of pixel circuits of imaging elements and readout circuits and the bright-time FPN is caused by variations in characteristics of photoelectric conversion elements. The intensity of the bright-time FPN increases with increase in intensity (the number of photons) of incident light.

Since the FPN does not vary with time and it is spatially fixed as a variation of characteristics of the imaging pixel, it can be reduced by appropriate signal processing. For example, to reduce the dark-time FPN, a method is known that stores a signal in a dark state to a memory in advance and subtracts the signal from a detection signal of a photodetector.

To reduce the bright-time FPN, a method is known that prepares one or two reference signals when the sensor device is illuminated with uniform reference lights having different intensities and subtracts a reference signal from a detection signal. JP 2015-100099 A proposes another method of reducing the bright-time FPN by dividing a detection signal by a reference signal under uniform reference light.

### SUMMARY

An aspect of this disclosure is a sensor device including: a plurality of pixels; and a controller configured to correct measurement signals of the plurality of pixels, wherein each of the plurality of pixels includes: a photodetector; and a pixel circuit configured to output a signal from the photodetector, and wherein the controller is configured to: acquire an unknown measured signal from one of the plurality of pixels; and correct the unknown measured signal of the one pixel with a correction coefficient which is based on ratios between values obtained from measured signals of the one pixel under a plurality of reference lights having different intensities and statistic values obtained from the values obtained from the measured signals of the plurality of pixels under a plurality of reference lights having different intensities.

An aspect of this disclosure is a method of determining correction coefficients to be used by a controller of a sensor device in correcting measurement signals of a plurality of pixels of the sensor device, each of the plurality of pixels including a photodetector and a pixel circuit configured to output a signal from the photodetector, and the method including: acquiring measured signals from the plurality of pixels under a plurality of reference lights having different intensities; determining a statistic value of the measured signals over the plurality of pixels under each of the plurality of reference lights; and determining a correction coefficient for each pixel based on the statistic value of the measured signals over the plurality of pixels and a measured signal of the pixel under each of the plurality of reference lights.

It is to be understood that both the foregoing general description and the following detailed description are exemplary and explanatory and are not restrictive of this disclosure.

### BRIEF DESCRIPTION OF THE DRAWINGS

FIG. 1 is a block diagram illustrating a configuration example of an image sensor related to Embodiment 1.

FIG. 2 schematically illustrates a configuration example of a main controller.

FIG. 3 is a circuit diagram illustrating an example of the circuit configuration of a pixel.

FIG. 4 is a signal flowchart illustrating a calculation method for noise reduction according to a related art.

FIG. 5 provides experimental results of noise reduction from a measurement signal in accordance with the related art.

FIG. 6 provides experimental results of noise reduction from a measurement signal in accordance with the related art.

FIG. 7 is a signal flowchart illustrating a calculation method for noise reduction in an embodiment of this specification.

FIG. 8 is a signal flowchart illustrating a method of determining weight coefficients in an embodiment of this specification.

FIG. 9 provides examples of raw measurement data of a pixels before the noise therein is removed.

FIG. 10 provides results of correction in accordance with the related art described with reference to FIG. 4.

FIG. 11 provides results of correction in accordance with the embodiment described with reference to FIGS. 7 and 8.

FIG. 12 illustrates relations between the intensity of illuminating light and the effective voltage of the noise in the rectangular regions surrounded by a dashed line in FIGS. 10 and 11.

FIG. 13 illustrates relations between the intensity of illuminating light and the effective voltage of the noise in Embodiment 2.

FIG. 14 illustrates an example of the photoelectric conversion characteristic of a pixel including a photodiode.

FIG. 15 illustrates an example of the noise voltage characteristic of a pixel;

FIG. 16 schematically illustrates a cross-sectional structure of an OLED panel with a sensor.

FIG. 17 schematically illustrates an example of the cross-sectional structure of a photosensor array.

FIG. 18 schematically illustrates a cross-sectional structure of an X-ray sensor panel.

### EMBODIMENTS

Hereinafter, an image sensor of this disclosure will be described in detail with reference to drawings. The elements in each drawing are changed in size or scale as appropriate to be well recognized in the drawing. The hatches in the drawings are to distinguish the elements and are not necessarily to represent cross-sections. The non-linear elements used as switching elements or amplifying elements are referred to as transistors. The transistors include thin-film transistors (TFTs).

In this specification, the term “light” includes visible light and electromagnetic rays having wavelengths shorter or longer than the visible light unless specified otherwise. For example, light includes infrared rays and ultraviolet rays and also X-rays, which are electromagnetic rays having a shorter wavelength. That is to say, a photodetector or a photoelectric conversion element is an element that converts electromagnetic rays having a specific wavelength into an electric signal unless specified otherwise.

### Embodiment 1

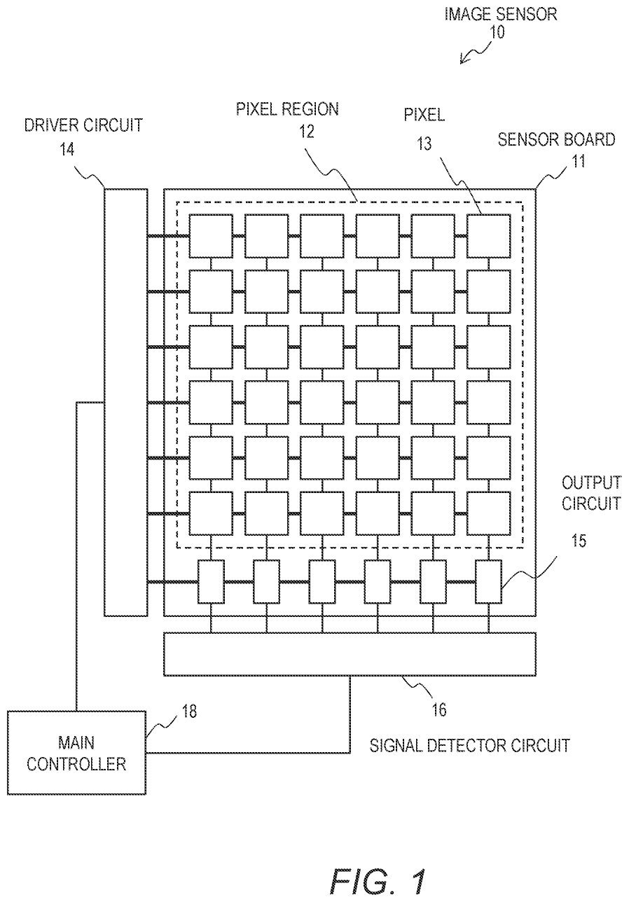

FIG. 1 is a block diagram illustrating a configuration example of an image sensor related to Embodiment 1. The image sensor 10 of this disclosure includes a sensor board 11 and a control system. The control system includes a driver circuit 14, a signal detector circuit 16, and a main controller 18.

The sensor board 11 includes an insulating substrate (such as a glass substrate), a pixel region 12 in which pixels 13 are arrayed horizontally and vertically like a matrix on the insulating substrate and output circuits 15. The pixel region 12 may include scintillator that emits fluorescence in response to radial rays to be detected. The driver circuit 14 drives the pixels 13 for the pixels 13 to detect light. The signal detector circuit 16 detects signals from the output circuits 15 of individual signal lines. The main controller 18 controls the driver circuit 14 and the signal detector circuit 16.

The driver circuit 14 and the signal detector circuit 16 in this embodiment are fabricated as components separate from the sensor board 11. These circuits can be implemented in different IC chips; a part or all of these circuits can be implemented in one same IC chip; or one circuit can be implemented in multiple IC chips.

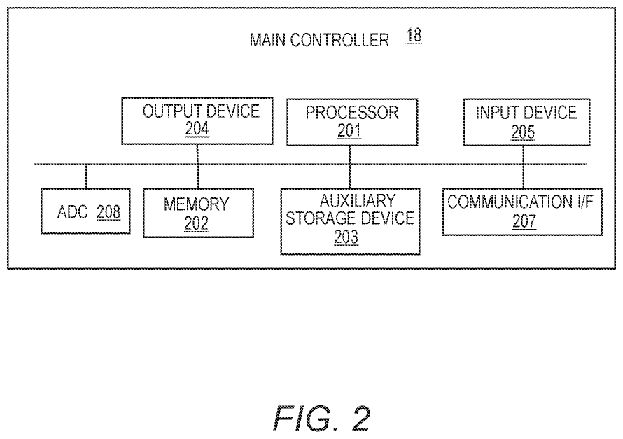

The main controller 18 can have a computer configuration. FIG. 2 schematically illustrates a configuration example of the main controller 18. The main controller 18 of the configuration example in FIG. 2 includes a processor 201, a memory (primary storage device) 202, an auxiliary storage device 203, an output device 204, an input device 205, a communication interface (I/F) 207, and an AD conversion interface (ADC) 208. These elements are interconnected by a bus. The memory 202, the auxiliary storage device 203, or the combination of these is a storage device for storing programs and data to be used by the processor 201.

The memory 202 can be a semiconductor memory and is mainly used to hold programs being executed and data. The processor 201 performs a variety of processing in accordance with the programs stored in the memory 202 to implement various function units.

The auxiliary storage device 203 can be a large-capacity storage device such as a hard disk drive or a solid-state drive; it is used to hold programs and data on a long-term basis.

The processor 201 can be one or more processing units and include one or more computing units or a plurality of processing cores. The processor 201 can be implemented as one or more central processing units, microprocessors, microcomputers, microcontrollers, digital signal processors, state machines, logic circuits, graphic processing units, chip-on systems, and/or any device that operates a signal in accordance with control instructions.

The programs and data stored in the auxiliary storage device 203 are loaded to the memory 202 at the start-up or when needed and the programs are executed by the processor 201 to perform a variety of processing of the main controller 18. Accordingly, the processing performed in accordance with a program is processing performed by the processor 201 or the main controller 18.

The input device 205 is a hardware device for the user to input instructions and information to the main controller 18. The output device 204 is a hardware device for presenting images for input and output, such as a display device or a printing device. The AD conversion interface 208 is an interface for converting an input analog signal to a digital signal. The communication I/F 207 is an interface for connecting to a network. The input device 205 and the output device 204 are optional and the main controller 18 can be accessed from a terminal via the network.

The functions of the main controller 18 can be implemented in a computer system that includes one or more computers equipped with one or more processors and one or more storage devices including a non-transitory storage medium. The computers communicate with one another via a network. For example, a part of the functions of the main controller 18 can be implemented in one computer and another part can be implemented in another computer.

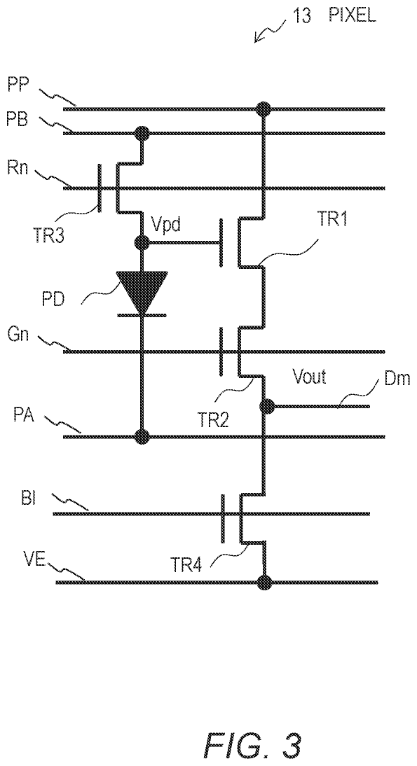

FIG. 3 is a circuit diagram illustrating an example of the circuit configuration of one pixel 13. The illustrated in FIG. 3 is an example of a pixel circuit and other circuit configurations can be employed. One pixel 13 in the image sensor of this disclosure includes four transistors TR1, TR2, TR3, and TR4 and a photodiode PD.

The photodiode PD is an example of a photodetector (also referred to as photoelectric conversion element). In the example illustrated in FIG. 3, the anode terminal of the photodiode PD is connected to the gate terminal of the transistor TR1 and the drain terminal of the transistor TR3. The cathode terminal of the photodiode PD is connected to a power line PA. The drain terminal of the transistor TR1 is connected to a power line PP and the source terminal of the transistor TR1 is connected to the drain terminal of the transistor TR2.

The gate terminal of the transistor TR2 is connected to a control line Gn and the source terminal of the transistor TR2 is connected to a signal line Dm. The gate terminal of the transistor TR3 is connected to a control line Rn and the source terminal of the transistor TR3 is connected to a power line PB. The gate terminal of the transistor TR4 is connected to a bias line BI; the drain terminal of the transistor TR4 is connected to the signal line Dm; and the source terminal of the transistor TR4 is connected to a power line VE. The power supply potential of the power line VE is lower than the power supply potential of the power line PP. The bias line BI supplies a constant bias potential to the gate terminal of the transistor TR4.

The photodiode PD has a function to convert light to electric charge. The transistor TR1 (amplifier transistor) has a function to amplify the potential at one end of the photodiode PD. The transistor TR2 has a function to control the output. The transistor TR3 has a function to reset the potential of the photodiode PD. The transistor TR4 functions as a resistor. The signal line Dm transmits a photodetection signal Vout of the photodiode PD to the signal detector circuit 16. The driver circuit 14 supplies control signals and power supply potentials to the control lines and power lines shown in FIG. 3.

Hereinafter, processing of the main controller 18 is described. The main controller 18 corrects measurement signals on the light detected by individual pixels 13 on the sensor board 11 to reduce the noise therein. The noise included in the measurement signal (output signal) from a pixel 13 is categorized into random noise that varies with time and fixed pattern noise (FPN) that does not vary with time.

The fixed pattern noise is further categorized into two kinds of FPN: dark-time FPN that is observed when the photoimaging element is not receiving light and bright-time FPN that varies in intensity depending on the intensity of incident light. It is known that the dark-time FPN is caused by variations in input and output characteristics of the pixel circuits and readout circuits. The bright-time FPN is caused by variations in characteristics of the photodiodes and its intensity increases with increase in the intensity (the number of photons) of incident light. The FPN does not vary with time but is spatially fixed as a variation in characteristics of the pixel. The processing described in the following reduces the dark-time FPN and the bright-time FPN. In the following description, the dark-time FPN is also referred to as additive FPN and the bright-time FPN as multiplicative FPN.

An embodiment of this specification assumes the following noise model for the measurement signal from a photodiode:

Sx=So+A*So+Rd (1)

where Sx represents a measurement signal of a pixel that includes noise; Rd represents a measurement signal in a dark state, namely an additive FPN; So represents a true photodetection signal that does not include noise; and A represents a multiplicative FPN coefficient.

The main controller 18 corrects the measurement signal Sx received from a pixel 13 by removing the additive FPN and the multiplicative FPN from the measurement signal Sx to obtain the true photodetection signal So.

Before describing signal processing for noise reduction in an embodiment of this specification, signal processing for noise reduction in a related art is described. The related art prepares three kinds of measurement data, which are of a measurement signal Rd in a dark state, a measurement signal RI when the sensor device is illuminated with uniform light, and a measurement signal Sx in an actual use state from which the true photodetection signal So is to be extracted.

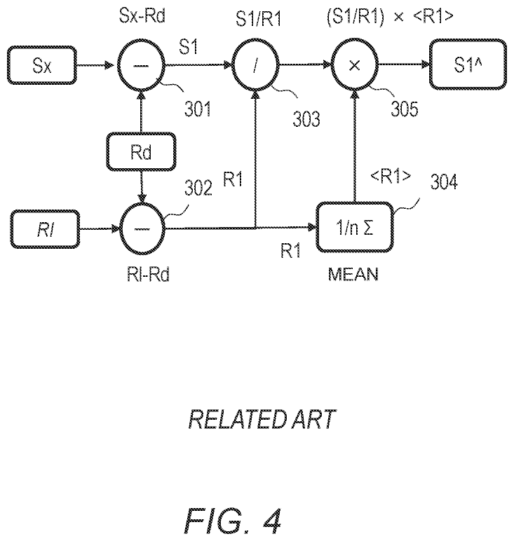

FIG. 4 is a signal flowchart illustrating a calculation method for the noise reduction according to the related art. The related art acquires dark-state measurement signals Rd from all pixels 13 and thereafter, acquires a measurement signal Sx to be corrected from one selected pixel 13. The ideal dark state for the measurement is a state where light weaker than the detectable limit of the pixels 13 exists but a state where light weaker than a threshold in accordance with the design exists is acceptable.

The related art subtracts the dark-state measurement signal Rd of the selected pixel 13 from the measurement signal Sx to acquire a signal S1 (301):

S1=Sx−Rd (2)

This processing removes the additive FPN from the measurement signal Sx of the selected pixel 13.

The related art further subtracts the dark-state measurement signal Rd from the measurement signal RI in a state where the sensor device is illuminated with uniform light (reference light), namely a bright state, to acquire a signal R1 with respect to every pixel 13 (302):

R1=RI−Rd (3)

The intensity of the uniform light is in the range detectable by the pixels 13 and it is much higher than the intensity of light existing in the dark state.

This processing removes the additive FPN from the measurement signal R1 under uniform light.

The related art divides the signal S1 of the selected pixel 13 by the signal R1 of the same pixel (303). The related art further calculates the mean <R1> of the signals R1 of all pixels 13 (304). The related art further removes the multiplicative FPN included in the signal S1 by the following calculation (305):

So\hat{ }=(S1/R1)*<R1> (4)

where So\hat{ } represents the estimated value of the true photodetection signal So that does not include noise.

The reason why the related art presumes that S1\hat{ } is the true photodetection signal So is described. According to the foregoing noise model, the following relation is established:

S1=So*(1+A) (5)

In similar, the following relation is also established:

R1=Ro*(1+A) (6)

where Ro represents the true photodetection signal in the measurement signal R1.

The related art assumes that the mean <R1> of the signals R1 of all pixels is the true signal value Ro of the signal R1:

Ro=<R1>*(1+A) (7)

The related art calculates the multiplicative FPN coefficient A from the formula (7) and assigns it to the formula (5) to calculate the estimated value So\hat{ } of the true photodetection signal So in the measurement signal Sx.

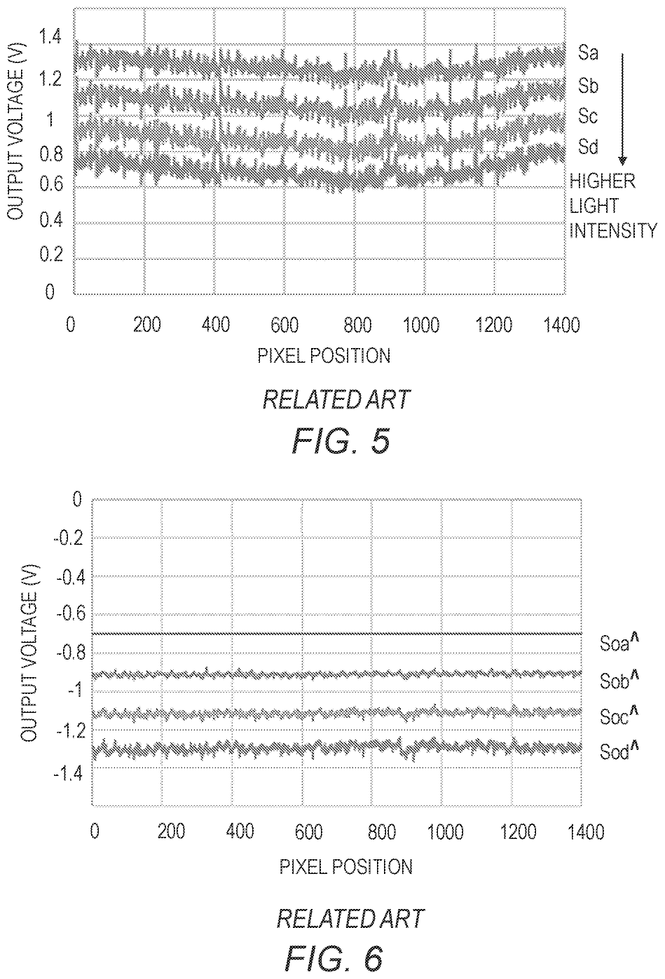

FIGS. 5 and 6 provide experimental results of noise reduction from the measurement signal Sx in accordance with the related art. FIG. 5 provides measurement signals (raw data) acquired under conditions of exposure to four uniform lights having different intensities. In the graph of FIG. 5, the horizontal axis represents the pixel position in the row or column direction and the vertical axis represents the output voltage of the pixel.

The intensity of illuminating light for the measurement signals Sa, Sb, Sc, and Sd increases in this order. The signal Sd is the measurement signal when the light intensity is highest and the signal Sa is the measurement signal when the light intensity is lowest. As shown in FIG. 5, each measurement signal exhibits large noise.

FIG. 6 provides results Soa\hat{ }, Sob\hat{ }, Soc\hat{ }, and Sod\hat{ } obtained by reducing the noise from the measurement signals Sa, Sb, Sc, and Sd in accordance with the formula (4), using the measurement signal Sa as the reference signal RI. As indicated by the signal Soa\hat{ }, the noise in the measurement signal Sa is completely removed. This is because S1=R1 in the formula (4).

However, the FPN in the measurement signals Sb, Sc, and Sd becomes larger as the illumination level deviates from the illumination level for the measurement signal Sa. For this reason, the multiplicative FPN cannot be removed completely by the processing in accordance with the formula (4) when the exposure condition deviates largely from the one for the reference signal Sa, as shown in the signal Sod\hat{ }, for example.

Next, signal processing to reduce the noise in the measurement signal from a photodiode in an embodiment of this specification is described. An embodiment of this specification uses a correction coefficient based on a plurality of reference signals under the reference lights having different intensities (measurement signals in response to such reference light) to correct a measurement signal. This configuration effectively removes the noise from the measurement signal. The wavelength components of the reference lights having different intensities can be the same. The intensities and the wavelength components for the reference light can be determined appropriately depending on the characteristics of the light to be detected by the image sensor 10.

The main controller 18 corrects the light measurement signal Sx from one pixel 13 using a correction coefficient based on a plurality of reference lights having different intensities. As a result, the noise components in the measurement signal Sx from a pixel 13 are effectively removed to obtain an estimated true photodetection signal So. As indicated in the noise model of the formula (1), the measurement signal Sx includes additive FPN and multiplicative FPN.

The example described in the following reduces the additive FPN and the multiplicative FPN. The coefficient based on a plurality of intensities of reference light are used to reduce the multiplicative noise. If the additive FPN is small, the calculation for reducing the additive FPN can be skipped. The main controller 18 corrects the measurement signal Sx of each pixel 13 to obtain an estimated value So\hat{ } of the true signal:

So\hat{ }=(Sx−Rd)*f (8)

where Rd represents the dark-state measurement signal Rd of a pixel 13 and it is the correction coefficient for reducing the additive FPN; f is the correction coefficient for reducing the multiplicative FPN and it is determined based on the measurement results under a plurality of reference lights having different intensities.

In an embodiment of this specification, the correction coefficient for a given pixel is based on the ratios of statistic values obtained from the measurement signals of a plurality of pixels to values obtained from the measurement signals of the pixel under the plurality of intensities of reference light. In an embodiment of this specification, the correction coefficient can be expressed as a linear combination of the above-described ratios under the plurality of intensities of reference light and weight coefficients.

In actual use, the main controller 18 has predetermined correction coefficients Rd and f specific to each pixel 13 and corrects measurement signals Sx of individual pixels 13 using their correction coefficients Rd and f to obtain estimated values So\hat{ } for the true light detection signals. The main controller 18 can hold other coefficients to calculate the coefficient f.

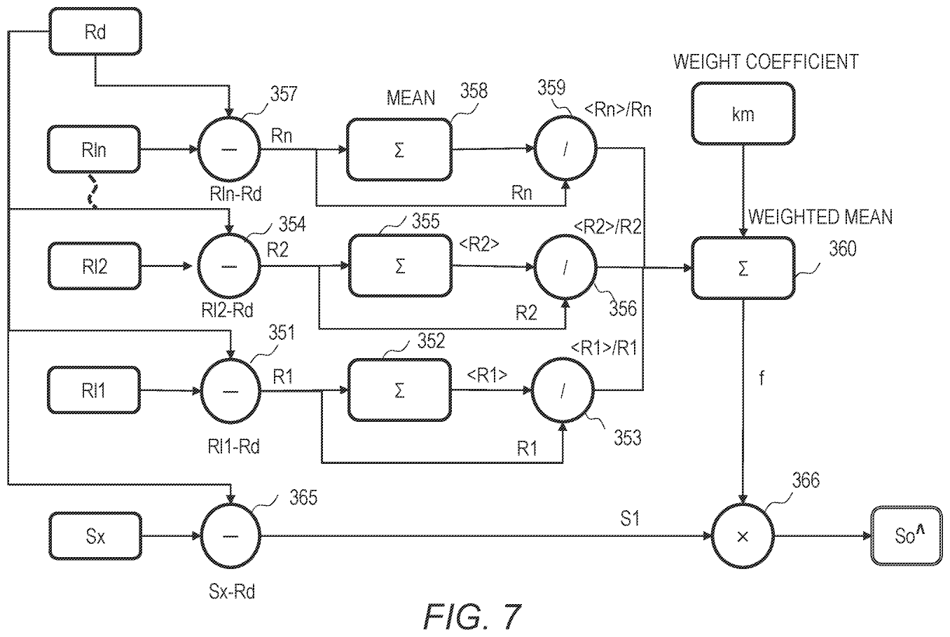

A method of determining the correction coefficient f is described. For example, the main controller 18 or a manufacturing apparatus of the image sensor 10 can determine the correction coefficient f. FIG. 7 is a signal flowchart illustrating a calculation method for noise reduction in an embodiment of this specification.

The flowchart of FIG. 7 illustrates a method of calculating the correction coefficient f for one selected pixel 13 and a method of correcting a measurement signal Sx of the pixel 13 using the correction coefficients Rd and f. The following description is based on an assumption that the main controller 18 executes the processing in FIG. 7. The description about one reference signal provided with reference to FIG. 4 is applicable to the processing about each intensity of reference light in FIG. 7.

The main controller 18 acquires dark-state measurement signals Rd and measurement signals Rl1 to Rln under the first to n-th intensities of reference light (unform light) (n is an integer greater than 1) from all pixels 13. The measurement signals Rd and RI1 to Rln can be acquired from only some of the pixels 13.

The main controller 18 subtracts the measurement signal Rd from the measurement signal Rl1 to obtain R1 with respect to each pixel 13 (351):

R1=Rl1−Rd (9)

This processing removes the additive FPN from the measurement signal Rl1 when the sensor device 10 is illuminated with uniform light.

The main controller 18 further calculates the mean <R1> of R1 of all pixels 13 (352). The main controller 18 divides the mean <R1> by the signal R1 of the selected pixel 13 (353):

<R1>/R1 (10)

Instead of the mean, a statistic such as the median can be employed.

The main controller 18 performs the foregoing processing for the signal R1 on the signals R2 to Rn under the other reference light. For example, the main controller 18 performs the processing 354, 355, and 356 on the measurement signal R2 and performs the processing 357, 358, and 359 on the measurement signal Rn.

Next, the main controller 18 calculates the weighted mean of <R1>/R1 to <Rn>/Rn using the weight coefficients k1 to kn calculated and stored in advance (360), assuming that the weight coefficients k1 to kn are normalized and their sum is 1:

Σkm*<Rm>/Rm (11)

where m is each of 1 to n.

This weighted mean is used as the correction coefficient f. As understood from this description, using measurement signals under reference lights having different intensities enables more appropriate correction to the measurement signal Sx that may take various intensities. Furthermore, assigning a weight coefficient to each intensity of reference light enables more appropriate correction to the measurement signal Sx. Although the values of the weight coefficients depend on the image sensor 10, at least some of the weight coefficients are usually different values.

The main controller 18 subtracts the dark-state measurement signal Rd of the selected pixel 13 from the measurement signal Sx to obtain a signal S1 (365):

S1=Sx−Rd (12)

This processing removes the additive FPN from the measurement signal Sx to be corrected.

Next, the main controller 18 multiplies the signal S1 by the coefficient f to calculate the estimated value So\hat{ } of the true photodetection signal of the selected pixel 13 (366):

So\hat{ }=S1*f (13)

As described above, an embodiment of this specification obtains a multiplicative noise factor specific to each pixel from a plurality of reference signals under uniform lights having different intensities and corrects the unknown measured signal of each pixel using the factor. As a result, the noise can be reduced effectively in a wide range of illumination intensity.

Next, a method of determining the weight coefficients k1 to kn is described. An embodiment of this specification determines the weight coefficients k1 to kn to minimize the effective voltage of the overall noise in the signals from all pixels illuminated with uniform reference light. The weight coefficients can be determined appropriately depending on the design of the image sensor 10. The main controller 18 or a manufacturing apparatus of the image sensor 10 can determine the weight coefficients k1 to kn. The following description is based on an assumption that the main controller 18 determines the weight coefficients k1 to kn.

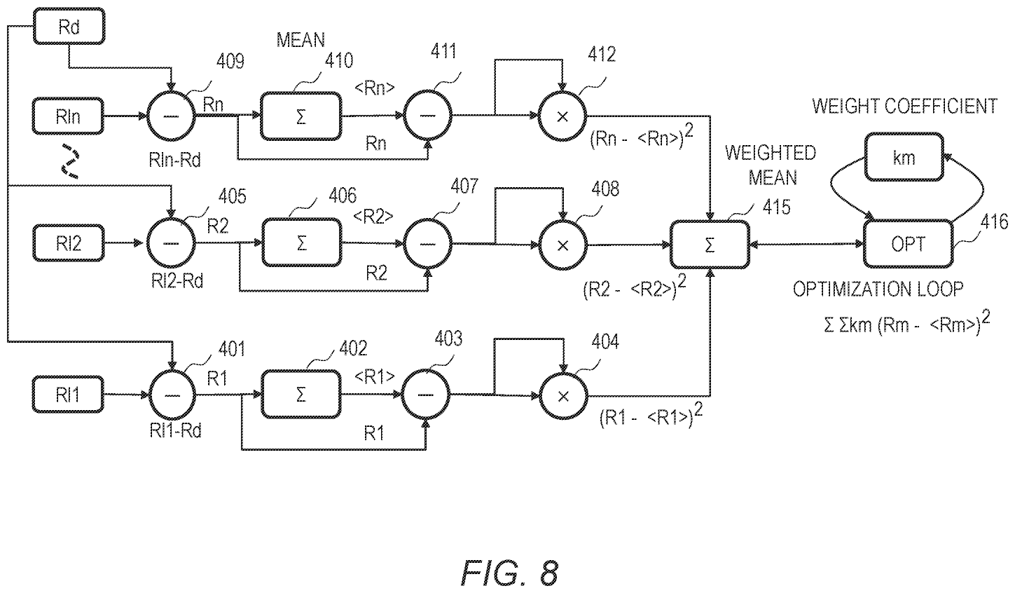

FIG. 8 is a signal flowchart illustrating a method of determining the weight coefficients in an embodiment of this specification. The main controller 18 subtracts the measurement signal Rd from the measurement signal RI1 to obtain RI with respect to each pixel 13 (401):

R1=Rl1−Rd (14)

Next, the main controller 18 calculates the mean <R1> of R1 of all pixels 13 (402). Further, the main controller 18 subtracts the mean <R1> from the signal R1 of each pixel 13 (403). The main controller 18 calculates the square value (R1−<R1>)² of the difference between the signal R1 and the mean <R1> with respect to each pixel 13 (404).

The main controller 18 performs the foregoing processing for the signal R1 on the other signals R2 to Rn under the other intensities of reference light. For example, the main controller 18 performs the processing 405 to 408 on the signal R2 and the processing 409 to 412 on the signal Rn.

Next, the main controller 18 calculates the weighted mean of the squared deviations from the mean, using the signals RI to Rn under all levels of reference light from all pixels (415). More specifically, the main controller 18 calculates the product sum (linear combination) of (Rm−<Rm>)² and the weight coefficient km with respect to each pixel 13 and further, calculates the sum of the values obtained from all pixels 13:

ΣΣkm*(Rm−<Rm>)² (15)

where m is each of the integers 1 to n and the weight coefficients are normalized.

In the formula (15), the first Σ means SUM with respect to all pixels. The second Σ means SUM with respect to all n intensities of reference light at each pixel 13. The main controller 18 determines the weight coefficients k1 to kn by an optimization loop to minimize the value obtained by the formula (15) (416).

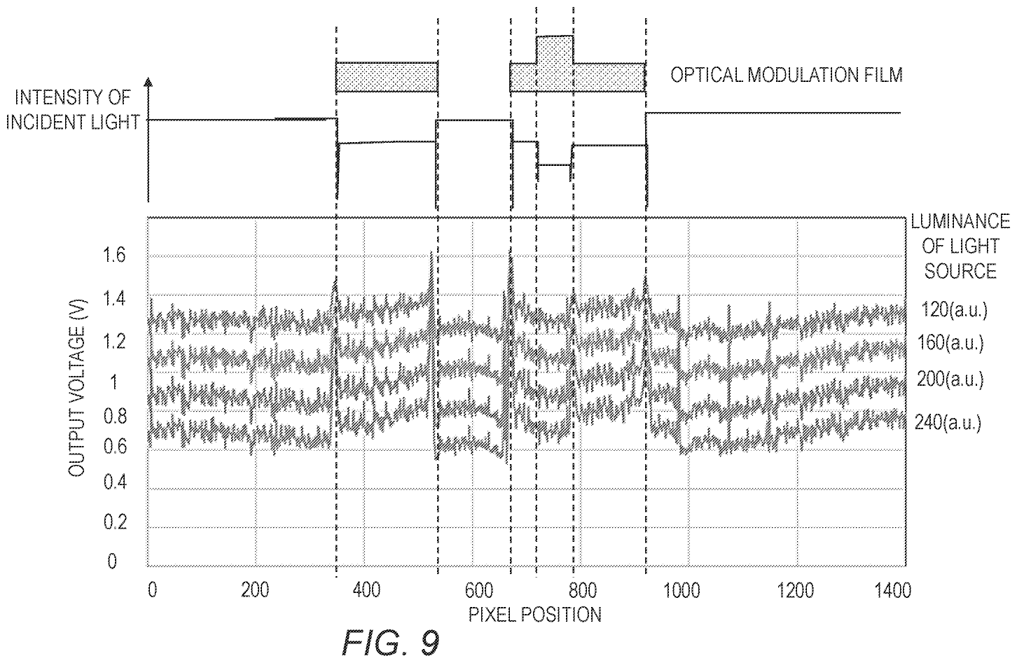

Hereinafter, effects of the correction of the measurement signal from a pixel 13 in an embodiment of this specification is described. FIG. 9 provides examples of raw measurement data of pixels 13 before the noise therein is removed. In the graph of FIG. 9, the horizontal axis represents the pixel position and the vertical axis represents the output voltage (V) from the pixels 13. FIG. 9 provides measurement signals Rl1 to Rl4 in response to four different intensities of illuminating light. The luminance (a.u.) of the light sources are 120, 160, 200, and 240.

The measurement supplied the pixel array with a pseudo-optical signal generated by optical modulation films each made of one or two transparent PET films. The prominent peaks in FIG. 9 indicate that the intensity of light is lowered because of the end faces of the films. When the output voltage is low, it means that the illuminance is high.

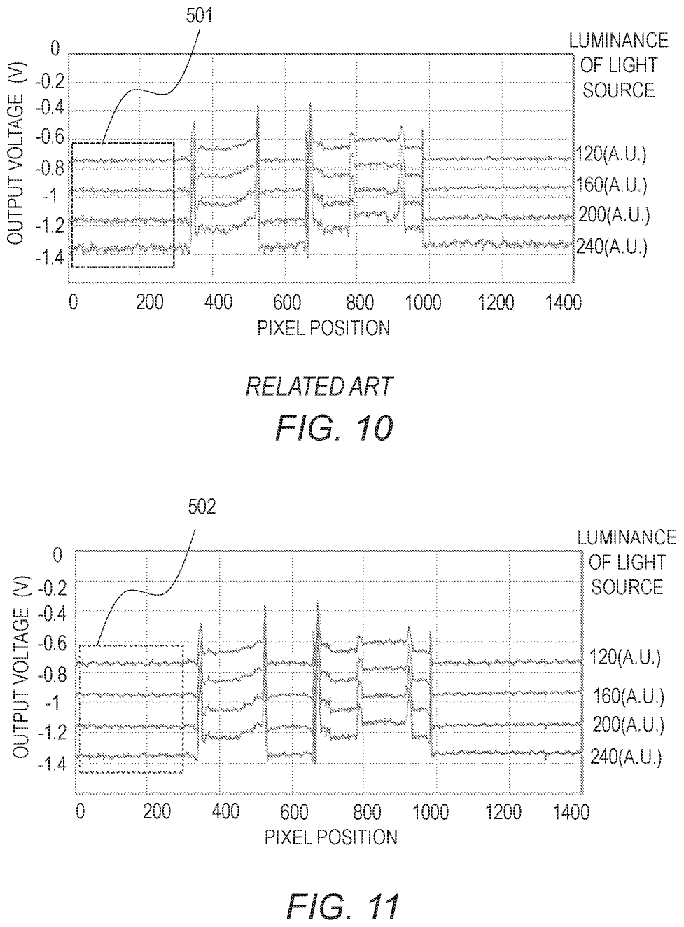

FIG. 10 provides results of the correction in accordance with the related art described with reference to FIG. 4. The reference light was Rl1 and its intensity was 120. FIG. 11 provides results of the correction in accordance with the embodiment described with reference to FIGS. 7 and 8. All of the four intensities of light Rl1 to Rl4 were the reference light for determining the correction coefficient.

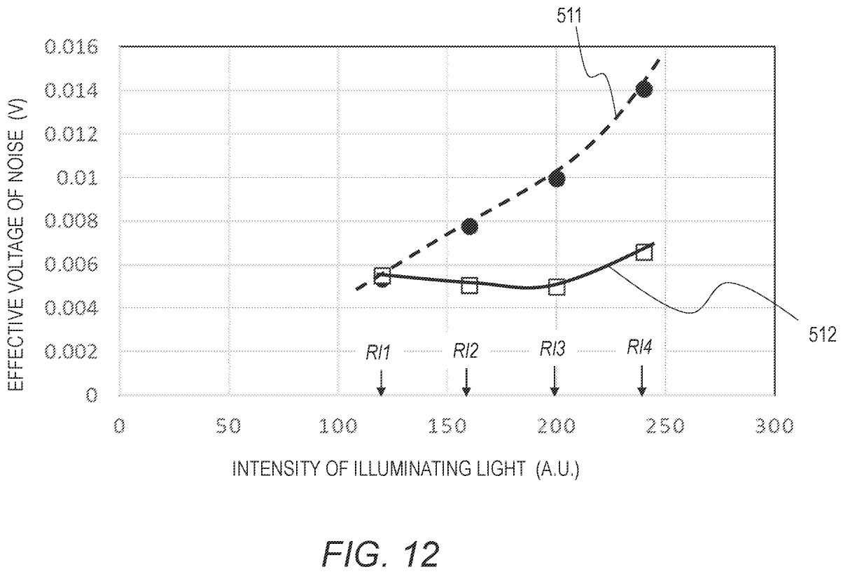

FIG. 12 illustrates relations between the intensity of illuminating light and the effective voltage of the noise in the rectangular region 501 surrounded by a dashed line in FIG. 10 and the rectangular region 502 surrounded by a dashed line in FIG. 11. In the graph of FIG. 12, the horizontal axis represents the intensity of reference light and the vertical axis represents the effective voltage (V) of the noise. The dashed line 511 represents the noise after correction in accordance with the related art and the solid line 512 represents the noise after correction in accordance with the embodiment of this specification. The intensities of the illuminating light Rl1 to Rl4 are 120, 160, 200, and 240 as described above.

As illustrated in FIG. 12, the results of correction in accordance with the related art indicate that the effective voltage of the noise increases as the intensity of illuminating light deviates from the intensity of the reference light Rl1. On the other hand, the results of correction in accordance with the embodiment of this specification indicate large noise reduction effect in a wide range of illumination intensity. As understood from FIG. 12, the correction in accordance with this embodiment can effectively reduce the noise in a wide range of illumination intensity.

### Embodiment 2

Hereinafter, signal processing to reduce the noise in a measurement signal from a photodiode in another embodiment of this specification is described. The noise reduction described in the following adaptively determines the correction coefficient for reducing the multiplicative FPN based on the intensity of the measurement signal. This configuration effectively reduces the noise in a wide range of illumination intensity.

The main controller 18 in this embodiment corrects the measurement signal Sx from each pixel 13 to obtain an estimated value So\hat{ } of the true signal, like the main controller 18 in Embodiment 1:

So\hat{ }=(Sx−Rd)*f (16)

In the formula (16), the measurement signal Sx and the correction coefficient Rd for the additive FPN are the same as those in the formula (8) in Embodiment 1. In other words, Rd is a measurement signal of each pixel 13 in a dark state. This embodiment is different from Embodiment 1 in the method of obtaining the correction coefficient f for the multiplicative FPN. The remaining is the same as Embodiment 1. In the following, the method of obtaining the correction coefficient f is described.

The noise reduction in this embodiment uses a plurality of reference signals acquired in response to a plurality of reference lights having different intensities to determine the correction coefficient, like in Embodiment 1. The example described in the following uses reference signals in response to two uniform reference lights having different intensities. Measurement signals in response to three or more reference lights having different intensities can be used. Like in Embodiment 1, the main controller 18 acquires the signals as listed below:
Measurement signal Sx to be corrected of one selected pixel,
Measurement signal Rl1 of each pixel under reference light 1,
Measurement signal Rl2 of each pixel under reference light 2, and
Measurement signal Rd of each pixel in a dark state.
The main controller 18 subtracts the dark-state measurement signal Rd of a selected pixel from the measurement signal Sx of the same pixel to obtain a signal S1:

S1=Sx−Rd (17)

This processing removes the additive FPN from the measurement signal Sx.

The main controller 18 subtracts the measurement signal Rd from the measurement signal Rl1 to obtain R1 with respect to each pixel 13. This processing removes the additive FPN from the measurement signal Rl1 under uniform light:

R1=Rl1−Rd (18)

Further, the main controller 18 subtracts the measurement signal Rd from the measurement signal Rl2 to obtain R2 with respect to each pixel 13. This processing removes the additive FPN from the measurement signal Rl2 under uniform light:

R2=Rl2−Rd (19)

The main controller 18 determines the mean <R1> of the signals R1 of all pixels 13 and the mean <R2> of the signals R2 of all pixels 13. Like in Embodiment 1, the values to be determined can be the means of some pixels or another statistic such as median. Next, the main controller 18 calculates weight coefficients that vary depending on the signal S1 having an unknown intensity by the following formulae. The following formulae determine the coefficients by linear interpolation. Assuming that <R1> is larger than <R2>, when the unknown signal S1 is equal to <R1>, k1=KMAX and k2=KMIN. When the unknown signal S1 is equal to <R2>, k1=KMIN and k2=KMAX. When <R1>>S1><R2>, k1 and k2 take values between KMAX and KMIN.

k1=KMIN+(S1−<R2>)*(KMAX−KMIN)/(<R1>−<R2>) and

k2=KMAX−(S1−<R2>)*(KMAX−KMIN)/(<R1>−<R2>) (20)

where KMAX and KMIN are constants and KMAX>KMIN.

The main controller 18 calculates the correction coefficient f for the multiplicative FPN in accordance with the following formula:

f=(k1*<R1>/R1+k2*<R2>/R2)/(k1+k2) (21)

The main controller 18 multiplies the signal S1 by the correction coefficient f to calculate an estimated value So\hat{ } of the true photodetection signal of the selected pixel 13:

So\hat{ }=S1*f (22)

For a simplest example, when determining <R1> to be the highest exposure

condition and <R2> to be the lowest exposure condition and assigning 1 to KMAX and 0 to KMIN, k1 and k2 take values between 0 and 1 However, the values of KMAX and KMIN are not limited to 1 and 0. In the case of assigning 1 to KMAX and 0 to KMIN and determining <R2> is a value larger than the lowest exposure condition, k1 may take a negative value when S1 is a value smaller than <R2>.

The weight coefficients k1 and k2 have to be positive values and therefore, in such a case, the negative value for k1 is avoided by assigning 1 to KMIN and 2 to KMAX, for example. Further, values optimized so that the effective voltage of the overall noise will be minimum can be assigned to KMAX and KMIN.

In the case of n (three or more) reference signals, the n coefficients k1 to kn can be determined using Lagrange interpolation. An example where n=3 is described. Assuming that <R3> is the highest exposure condition and <R1> is the lowest exposure condition, the main controller 18 determines the third exposure condition <R2> so that the condition <R3>><R2>><R1> is satisfied and introduces constants KMAX and KMIN, and the third constant KMID that satisfies KMAX>KMID>KMIN. Under these conditions, weight coefficients k1, k2, and k3 for the signal intensity S1 can be determined by quadratic Lagrange interpolation as follows:

$$k 1 = \{ ( S 1 - R 2 ) ( S 1 - R 3 ) / ( R 1 - R 2 ) / ( R 1 - R 3 ) \} KMAX + \{ ( S 1 - R 1 ) ( S 1 - R 3 ) / ( R 2 - R 1 ) / ( R 2 - R 3 ) \} KMID + \{ ( S 1 - R 1 ) ( S 1 - R 2 ) / ( R 3 - R 1 ) / ( R 3 - R 2 ) \} KMIN ;$$

$$k 2 = \{ ( S 1 - R 2 ) ( S 1 - R 3 ) / ( R 1 - R 2 ) / ( R 1 - R 3 ) \} KMIN + \{ ( S 1 - R 1 ) ( S 1 - R 3 ) / ( R 2 - R 1 ) / ( R 2 - R 3 ) \} KMAX + \{ ( S 1 - R 1 ) ( S 1 - R 2 ) / ( R 3 - R 1 ) ( R 3 - R 2 ) \} KMIN ; and$$

$$k 3 = \{ ( S 1 - R 2 ) ( S 1 - R 3 ) / ( R 1 - R 2 ) / ( R 1 - R 3 ) \} KMIN + \{ ( S 1 - R 1 ) ( S 1 - R 3 ) / ( R 2 - R 1 ) / ( R 2 - R 3 ) \} KMID + \{ ( S 1 - R 1 ) ( S 1 - R 2 ) / ( R 3 - R 1 ) / ( R 3 - R 2 ) \} KMAX$$

The main controller 18 can have <R1 >, <R2>, R1, R2, Rd, KMAX, and KMIN in advance. The main controller 18 can calculate the weight coefficients k1 and k2 from these values and the measurement signal Sx from a pixel 13 and further calculate the correction coefficient f. As described in Embodiment 1, the main controller 18 can measure the reference light and acquire Rl1 and Rl2 of each pixel 13.

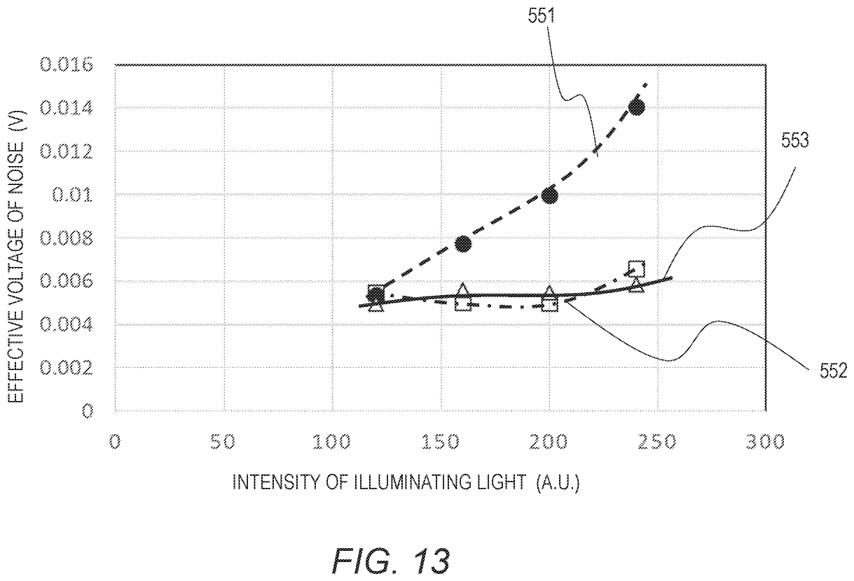

FIG. 13 illustrates relations between the intensity of illuminating light and the effective voltage of the noise. In the graph of FIG. 13, the horizontal axis represents the intensity of reference light and the vertical axis represents the effective voltage (V) of the noise. The dashed line 551 represents the noise after correction in accordance with the related art; the dashed-dotted line 552 represents the noise after correction in accordance with Embodiment 1; and the solid line 553 represents the noise after correction in accordance with Embodiment 2. In the correction in accordance with Embodiment 2, KMAX was 1.52 and KMIN was 0.25.

As indicated in FIG. 13, the result of the correction in Embodiment 2 exhibits stable effect of noise reduction in a wide range of illumination intensity, compared to the result of the correction in Embodiment 1.

### Other Embodiments

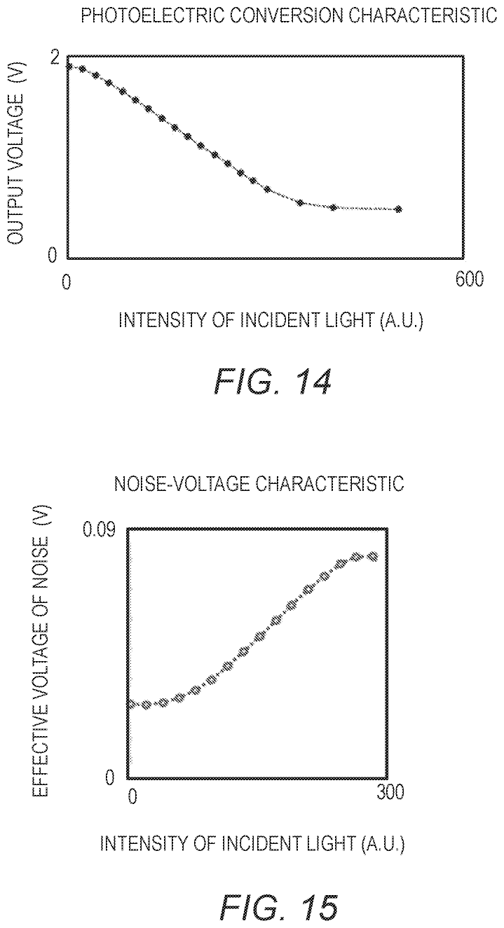

FIG. 14 illustrates an example of the photoelectric conversion characteristic of a pixel including a photodiode. FIG. 15 illustrates an example of the noise voltage characteristic of a pixel. As indicated in FIG. 14, the output voltage decreases with increase in intensity of incident light. As indicated in FIG. 15, the noise voltage increases with increase in intensity of incident light. This means that multiplicative noise exists. As described above, the signal correction methods according to the embodiments of this specification effectively remove not only the additive noise but also the multiplicative noise.

Hereinafter, some devices to which the processing to correct a measurement signal in the embodiments of this specification is applicable are described. The correction in the embodiments of this specification is applicable to devices including a plurality of pixels each including a photoelectric conversion element. The pixel layout can be in one or two dimensions.

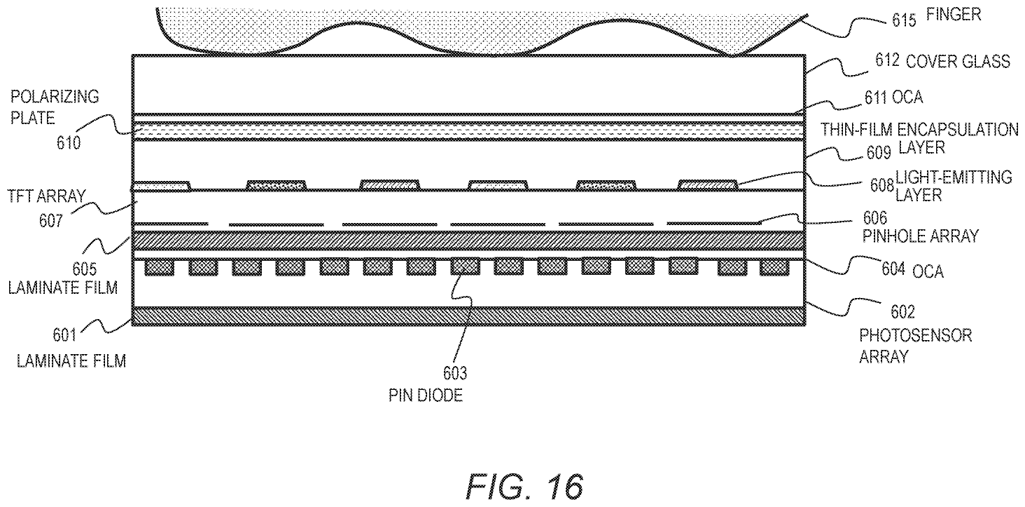

FIG. 16 schematically illustrates a cross-sectional structure of an organic light-emitting diode (OLED) panel with a sensor. The OLED panel with a sensor can detect the fingerprint of a finger 615. The OLED panel with a sensor includes a photosensor array 602 on a laminate film 601 of a substrate. The photosensor array 602 includes a plurality of PIN diodes 603. Each PIN diode 603 is included in a pixel. The processing for noise reduction in the above-described embodiments is applicable to the measurement signals of the photosensor array 602.

Another laminate film 605 is bonded to the photosensor array 602 with optical clear adhesive (OCA) 604. Above the laminate film 605, a pinhole array 606, a TFT array 607, and a plurality of light-emitting layers 608 are provided in layers. Each light-emitting layer 608 is the light-emitting layer of an OLED and the TFT array 607 controls light emission of the light-emitting layers 608.

The light-emitting layers 608 are covered with a thin-film encapsulation layer 609 and a polarizing plate 610 is provided above the thin-film encapsulation layer 609. A cover glass 612 is bonded to the polarizing plate 610 with OCA 611. A finger 615 is pressed against the surface of the cover glass 612.

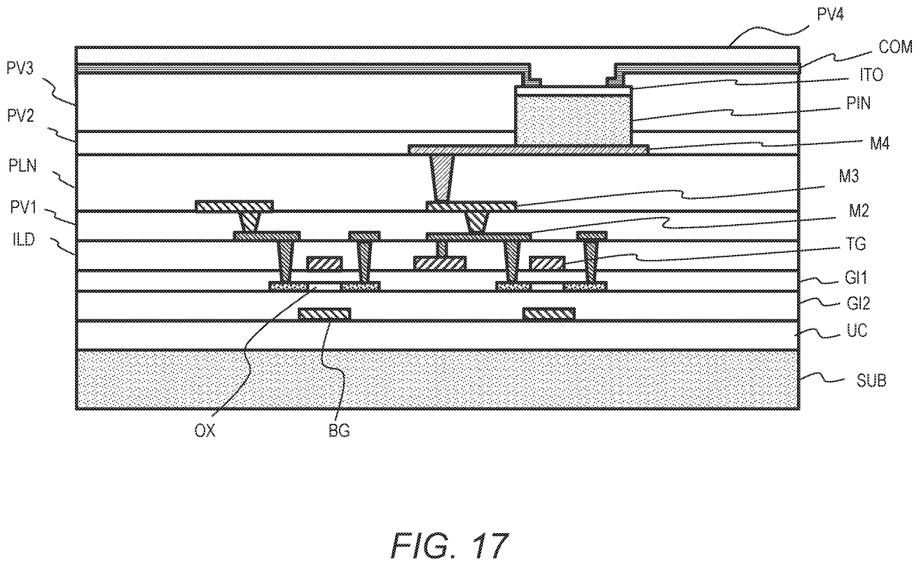

FIG. 17 schematically illustrates an example of the cross-sectional structure of the photosensor array 602. The substrate SUB corresponds to the laminate film 601 in FIG. 16. FIG. 17 illustrates two TFTs and one PIN diode by way of example.

An undercoat layer UC is provided above the substrate SUB and bottom gate electrodes BG are provided above the undercoat layer UC. In FIG. 17, the bottom gate electrode of one of the two TFTs is provided with a reference sign BG by way of example. The bottom gate electrodes BG are covered with a gate insulating layer Gl2. Semiconductor layers OX are provided above the gate insulating layer Gl2. In the example of FIG. 17, the semiconductor layers OX are made of an oxide semiconductor. The semiconductor material can be selected desirably. In FIG. 17, the semiconductor layer of one of the two TFTs is provided with a reference sign OX by way of example.

Another gate insulating layer Gl1 covers the semiconductor layers OX. A metal layer including top gate electrodes TG are provided above the gate insulating layer Gl1. In FIG. 17, the top-gate electrode of one of the two TFTs is provided with a reference sign TG by way of example.

The metal layer including the top-gate electrodes TG is covered with an interlayer insulating layer ILD. A metal layer M2 is provided above the interlayer insulating layer ILD. The metal layer M2 includes source electrodes and drain electrodes of the TFTs and further, contact regions extending through the insulating layer ILD or the insulating layers ILD and Gl1.

The metal layer M2 is covered with a passivation layer PV1. Another metal layer M3 is provided above the passivation layer PV1. The metal layer M3 includes lines and contact regions extending through the insulating passivation layer PV1.

The metal layer M3 is covered with a planarization layer PLN. Still another metal layer M4 is provided above the planarization layer PLN. The metal layer M4 includes lower electrodes of PIN diodes and further, contact regions extending through the insulating planarization layer PLN.

A part of the metal layer 4 is covered with a passivation layer PV2 and another passivation layer PV3 above the passivation layer PV2. A multi-layered semiconductor film PIN is provided above a lower electrode of the metal layer M4 within a hole opened through the passivation layers PV2 and PV3. The multi-layered semiconductor film consists of a p-type semiconductor layer, an n-type semiconductor layer, and an intrinsic semiconductor layer.

An upper electrode ITO is provided above the multi-layered semiconductor film PIN. The upper electrode ITO is transmissive for the light to be detected. A common electrode COM is connected to the upper electrode ITO of the PIN diode. The common electrode COM is connected to all PIN diodes. The uppermost passivation layer PV4 covers the upper electrode ITO and the common electrode COM.

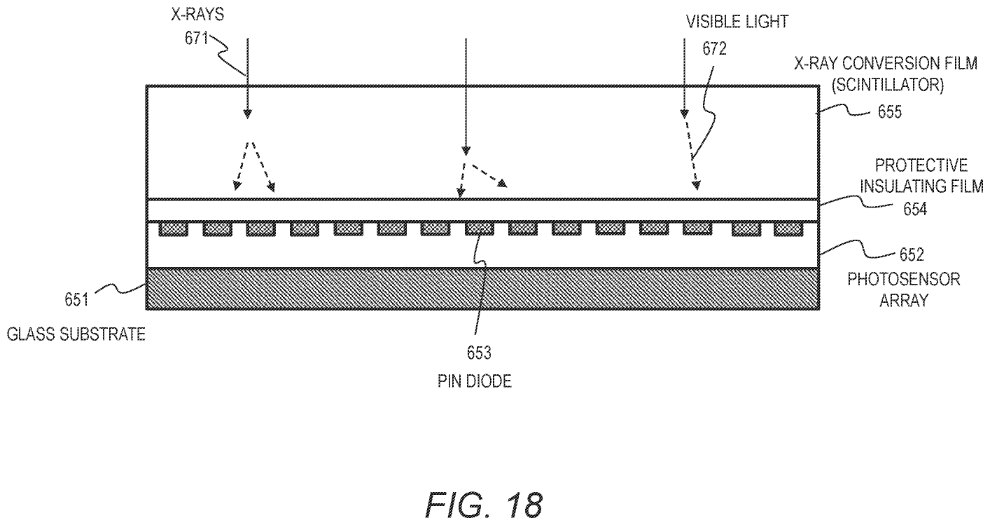

FIG. 18 schematically illustrates a cross-sectional structure of an X-ray sensor panel. The X-ray sensor panel is applicable to radiographic imaging devices in the fields of medical and industrial non-destructive testing. The X-ray sensor panel includes a photosensor array 652 on a glass substrate 651. The photosensor array 652 includes a plurality of PIN diodes 653. Each PIN diode 653 is included in a pixel. The processing for noise reduction in the above-described embodiments is applicable to measurement signals from the photosensor array 652.

The photosensor array 652 is covered with a protective insulating film 654. An X-ray conversion film (scintillator) 655 is provided above the protective insulating film 654. The X-ray conversion film 655 converts received X-rays 671 into visible light 672 detectable for the PIN diodes 653. Each pixel of the photosensor array 652 measures the intensity of the visible light converted by the X-ray conversion film 655.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A sensor device comprising:
a plurality of pixels; and
a controller configured to correct measurement signals of the plurality of pixels,
wherein each of the plurality of pixels includes:
a photodetector; and
a pixel circuit configured to output a signal from the photodetector, and
wherein the controller is configured to:
acquire an unknown measured signal from one of the plurality of pixels; and
correct the unknown measured signal of the one pixel with a correction coefficient which is based on ratios between values obtained from measured signals of the one pixel under a plurality of reference lights having different intensities and statistic values obtained from the values obtained from the measured signals of the plurality of pixels under a plurality of reference lights having different intensities.

2. The sensor device according to claim 1, wherein the correction coefficient is given by a linear combination of the ratios between the values obtained from the measured signals of the one pixel under the plurality of reference lights having different intensities and the statistic values obtained from the values obtained from the measured signals of the plurality of pixels under the plurality of reference lights having different intensities.

3. The sensor device according to claim 1, wherein each of the statistic values obtained from measured signals of the plurality of pixels is a mean of values each obtained by subtracting a measured signal of a pixel in a dark state from the measured signal of the pixel.

4. The sensor device according to claim 1, wherein the controller is configured to determine the correction coefficient based on the statistic values obtained from measured signals of the plurality of pixels under the plurality of reference lights having different intensities and the values obtained from measured signals of the one pixel under the plurality of reference lights having different intensities.

5. The sensor device according to claim 4,
wherein, in determining the correction coefficient, the controller is configured to:
calculate the statistic values over the plurality of pixels from values obtained after subtracting signals measured in a dark state from signals measured under the plurality of reference lights having different intensities;
obtain first differences by subtracting a signal of the one pixel measured in a dark state from signals of the one pixel measured under the plurality of reference lights having different intensities; and
calculate a linear combination of quotients obtained by dividing a statistic value by a first difference for each one of the plurality of reference lights and weight coefficients for each one of the plurality of reference lights, and
wherein, in correcting an unknown measured signal of the one pixel, the controller is configured to:
calculate a second difference by subtracting the signal of the one pixel measured in a dark state from the unknown measured signal of the one pixel; and
calculate a product of the second difference and the linear combination.

6. The sensor device according to claim 5, wherein the controller is configured to determine each of the weight coefficients for the plurality of reference lights having different intensities based on the statistic value for each one the plurality of reference lights and the unknown measured signal of the one pixel.

7. The sensor device according to claim 1, wherein the controller is configured to determine the correction coefficient based on the ratios under the plurality of reference lights having different intensities and the unknown measured signal of the one pixel.

8. The sensor device according to claim 1, wherein the correction coefficient f is expressed by a following formula:
f=Σkm*<Rm>/Rm,
where m represents an identifier of the plurality of reference lights having different intensities; km represents a weight assigned to reference light m; Rm represents the value obtained from a measured signal of the one pixel under the reference light m; and <Rm> represents the statistic value over the plurality of pixels under the reference light m.

9. The sensor device according to claim 8,
wherein a value So\hat{ } obtained by correcting the unknown measured signal is expressed by a following formula:
So\hat{ }=(Sx−Rd)*f,
where Sx represents the unknown measured signal and Rd represents a measured signal of the one pixel in a dark state,
wherein the value Rm obtained from a measured signal of the one pixel under the reference light m is expressed by a following formula:
Rm=Rlm−Rd,
where Rlm represents the measured signal of the one pixel under the reference light m, and
wherein the statistic value <Rm> under the reference light m is a mean of values over the plurality of pixels obtained after subtracting measured signals in a dark state from measured signals under the reference light m for each pixel.

10. A method of determining correction coefficients to be used by a controller of a sensor device in correcting measurement signals of a plurality of pixels of the sensor device,
each of the plurality of pixels including a photodetector and a pixel circuit configured to output a signal from the photodetector, and
the method comprising:
acquiring measured signals from the plurality of pixels under a plurality of reference lights having different intensities;
determining a statistic value of the measured signals over the plurality of pixels under each of the plurality of reference lights; and
determining a correction coefficient for each pixel based on the statistic value of the measured signals over the plurality of pixels and a measured signal of the pixel under each of the plurality of reference lights.
